(19) United States
(12) Patent Application Publication
(10) Pub. No.: US 2009/0252348 A1
(43) Pub. Date: Oct. 8, 2009

(54) ANTENNA IMPLEMENTATIONS IN INTERCONNECTING CABLES

(75) Inventor: John Glissman, Metro Manila (PH)

Correspondence Address: STAINBROOK & STAINBROOK, LLP, 412 AVIATION BOULEVARD, SUITE H, SANTA ROSA, CA, 95403, US

(73) Assignee: AERIELLE TECHNOLOGIES, INC, MOUTAIN VIEW, CA (US)

(21) Appl. No.: 12/301,048

(22) PCT Filed: May 18, 2007
(86) PCT No.: PCT/US07/69193

§ 371 Date: Nov. 17, 2008

Related U.S. Application Data
(60) Provisional application No. 60/863,538, filed on Oct. 30, 2006.
(60) Provisional application No. 60/747,497, filed on May 17, 2006.

(51) Int. Cl. H03G 3/00; H04B 7/24

(52) U.S. Cl. 381/107; 455/39

(57) ABSTRACT

Antenna system having as one element a conductors in an interconnecting cable, wherein that conductor is isolated at RF from the device at the opposite cable end, while also being tightly coupled to that device at audio frequencies and/or DC. Such an antenna is suited for use in wireless transmitters and receivers for transmitting a signal from an audio playback device to a remote audio out put device having multiple conductors interconnecting the wireless transmitter and media device, or multiple conductors interconnecting the receiver and headphones/speakers.

### BACKGROUND OF THE INVENTION

1. Technical Field

The present invention relates generally to the field of consumer electronics; and, more specifically, to the field of wireless transmitters and receivers; still more particularly to wireless transmitter and receivers used to transmit a signal from an audio playback device, such as a CD player, MP3 player, or Satellite Media receiver, to a remote receiver/speaker or headphone receiver system, wherein the audio playback device includes multiple conductors interconnecting the wireless transmitter and media device, or multiple conductors interconnecting the receiver and headphones/speakers.

2. Background Art

With the widespread use of portable AM/FM receivers, cassette, CD, and MP3 players, as well as other consumer electronic devices providing audio and data signal outputs, a need has arisen for more convenient methods for delivering those signals to the system user. Currently, users wear headphones connected to a signal-generating device by wires. These wires are inconvenient and possibly dangerous. In the case of portable audio devices, for instance, the devices are employed while users are engaged in other activities, such as jogging, rollerblading, manual labor, driving, etc. During such activities, wires are susceptible to being tangled up or providing a hindrance to efficient use. The same is true of wires leading from stationary devices such as a personal computer, motor vehicle dashboard, or rack mounted stereo. Therefore, as signal generating devices have proliferated, so too has the need to make them convenient.

Two examples of devices addressing these needs are disclosed in U.S. Pat. No. 5,771,441 for a Small Battery Operated Rf Transmitter For Portable Audio Devices For Use With Headphones With Rf Receiver, issued Jun. 23, 1998 to John E. Alstatt (hereinafter referred to as “Altstatt”), and in U.S. Pat. No. 6,671,494 for a Small Battery Operated Rf Transmitter For Portable Audio Devices For Use With Headphones With Rf Receiver, issued Dec. 30, 2003 to John James (hereinafter referred to as “James”). The Altstatt and the James patents are each incorporated in their entirety by reference herein.

In Alstatt, there is taught a portable RF transmitter that modulates audio signals from an audio source onto an FM carrier signal and then transmits such signals to an FM receiver mounted on a headset worn by a user. The RF transmitter uses its own ground circuit and the ground circuit of the audio source as two elements of a short dipole.

In James, there is taught a portable RF transmitter that modulates audio signals from an audio source onto an FM carrier signal and then transmits such signals to an FM receiver. The RF transmitter uses its own ground circuit as the first, and both the ground conductor of the cable interconnecting transmitter to the audio source, and the ground circuit of the audio source as the second of two elements of a dipole antenna.

A limitation in these approaches arises because the ground system of the source audio device is an active part of the antenna. As the typical audio source devices can be quite small, such as a portable flash-based MP3 player, or quite large, such as the CD player in a “boom box,” the physical size of the ground system, and consequently the antenna, can vary greatly. This makes the impedance of the antenna variable over a potentially large range at a given frequency, depending on the audio source used and the length of the conductors. This variable load impedance makes matching the RF source impedance to the RF load impedance a necessary compromise with maximum power transfer occurring at only the design physical composite antenna length. Accordingly, it remains desirable to provide an antenna system where one element is comprising one of the conductors in an interconnecting cable isolated at RF from the device at the opposite cable end, yet tightly coupled to that device at audio frequencies and/or DC.

The foregoing patents reflect the current state of the art of which the present inventor is aware. Reference to, and discussion of, these patents is intended to aid in discharging Applicant's acknowledged duty of candor in disclosing information that may be relevant to the examination of claims to the present invention. However, it is respectfully submitted that none of the above-indicated patents disclose, teach, suggest, show, or otherwise render obvious, either singly or when considered in combination, the invention described and claimed herein.

### DISCLOSURE OF INVENTION

Answering the need set out above, the intent of the present invention is to provide an antenna system in which one element comprises one of the conductors in an interconnecting cable, and such element is isolated at RF from the device at the opposite cable end, while also being tightly coupled to that device at audio frequencies and/or DC.

One typical interconnecting application involves utilizing three conductors in the interconnecting cable, one each connecting left and right audio circuits, and a third connecting a return circuit common to both the left and right audio circuits.

In the case of interconnecting an audio source to a transmitter, James teaches a method of using the common ground conductor and the ground system of the audio device as one element of a dipole. By adding a circuit element(s) at the connection point of this common ground to the audio ground of the audio source device that is a high impedance at RF but a low impedance at audio frequencies/DC [such as a series inductor (FIG. 1) or ferrite bead (FIG. 2), or series, parallel resonant at RF, inductor/capacitor tank circuit (FIG. 3)], the common audio conductor can be isolated from the audio device ground system, minimizing the variation in antenna impedance when using different audio source devices.

In such a case, the audio lines running in parallel with the common ground are usually very low impedance at RF, and so load the higher impedance antenna circuit, reducing its efficiency and lowering the apparent impedance. By adding the same circuit elements as above, in series, at both the source end and load end of the left and right channel audio circuits, the audio lines now become a much higher impedance at RF, and this loading effect can be minimized, thereby increasing antenna efficiency.

When all three conductors are thus isolated at RF from their respective source and load circuits, any or all of them can be utilized as the antenna element. As antenna efficiency is directly affected by “copper loss” (or more preferably “load loss”) and this resistance of the conductor is directly related to the conductor cross-sectional area, the most efficient antenna would be realized by using all of the conductors available.

In the foregoing case, one or two (or more) components are required at each end of each conductor, requiring six to twelve or more components for this three-conductor case. Another embodiment of this invention is to use a first, second, and third RF choke (inductor) at each end of the cable, wherein the first, second, and third RF chokes comprise the windings of a filar wire, common-mode radio frequency choke (FIG. 4), thus reducing the component count to two (2) in a three-conductor implementation.

The Rayleigh-Helmholtz reciprocity theorem, as generalized by Carson and applied to antennas, states that antennas are reciprocal, that is, the qualities that make an antenna efficient and effective in transmitting a signal also make it good at receiving a signal; or stated somewhat differently, an antenna works the same receiving as it does transmitting. Therefore, the principals of this invention can be applied to a receiving antenna as well.

In the case of interconnecting a pair of headphones to the audio output of a receiver, first each circuit conductor is isolated at RF by a series inductor, series ferrite bead, series parallel resonant inductor/capacitor tank circuit, or multi-filar common-mode RF choke at the receiver output. If only a single conductor is used as an antenna element, then similar RF isolation means would be placed at the transducer end of the conductors (FIG. 5). A small capacitor (low impedance at RF, high impedance at audio, and a DC block) is then used to connect the desired conductor to the receiver RF input. However, if all conductors are used (capacitors coupling each conductor into the receiver RF input) and equal in length, then the isolation means used at the transducer end would not be necessary (FIG. 6) if there is no differential RF voltage generated between conductors at the transducer end of the cable.

In another preferred embodiment, suited to the situation when there is a significant length of cable connecting the transmitter ground to the DC power source, is to implement a monopole antenna. By replacing the audio ground connection to the RF output of the transmitter chip with a terminating resistor to RF ground, the value of which approximates the output impedance of the RF chip, there is provided an antenna system that is not a dipole, but has radiation characteristics similar to the dipole implementations referenced above.

Other novel features characteristic of the invention, together with further objects and advantages thereof will be better understood from the following description considered in connection with the accompanying drawings, in which preferred embodiments of the invention are illustrated by way of example. It is to be expressly understood, however, that the drawings are for illustration and description only and are not intended as a definition of the limits of the invention. The various features of novelty which characterize the invention are pointed out with particularity in the claims annexed to and forming part of this disclosure. The invention resides not in any one of these features taken alone, but rather in the particular combination of all of its elements for the functions specified.

### BRIEF DESCRIPTION OF THE DRAWINGS

The invention will be better understood and objects other than those set forth above will become apparent when consideration is given to the following detailed description thereof. Such description makes reference to the annexed drawings wherein:

FIG. 1 is a circuit diagram of an embodiment of the present invention wherein a radio frequency transmitter output is capacitively coupled to audio signal wires for use as antenna elements, and inductors are used to isolate the audio and radio frequency signals;

FIG. 2 is a circuit diagram of an embodiment of the present invention wherein a radio frequency transmitter output is capacitively coupled to audio signal wires for use as antenna elements, and ferrite beads are used to isolate the audio and radio frequency signals;

FIG. 3 is a circuit diagram of an embodiment of the present invention wherein a radio frequency transmitter output is capacitively coupled to audio signal wires for use as antenna elements, and inductors and capacitors are used to isolate the audio and radio frequency signals;

FIG. 4 is a circuit diagram of an embodiment of the present invention wherein a radio frequency transmitter output is capacitively coupled to audio signal wires for use as antenna elements, and the windings of a filar-wire, common-mode radio frequency choke are used to isolate the audio and radio frequency signals;

FIG. 5 is a circuit diagram of an embodiment of the present invention wherein a radio frequency receiver input is capacitively coupled to audio signal wires for use as antenna elements, and inductors and capacitors are used to isolate the audio and radio frequency signals; and

FIG. 6 is a circuit diagram of an embodiment of the present invention wherein a radio frequency receiver input is capacitively coupled to audio signal wires for use as antenna elements, and ferrite beads are used to isolate the audio and radio frequency signals.

### BEST MODE FOR CARRYING OUT THE INVENTION

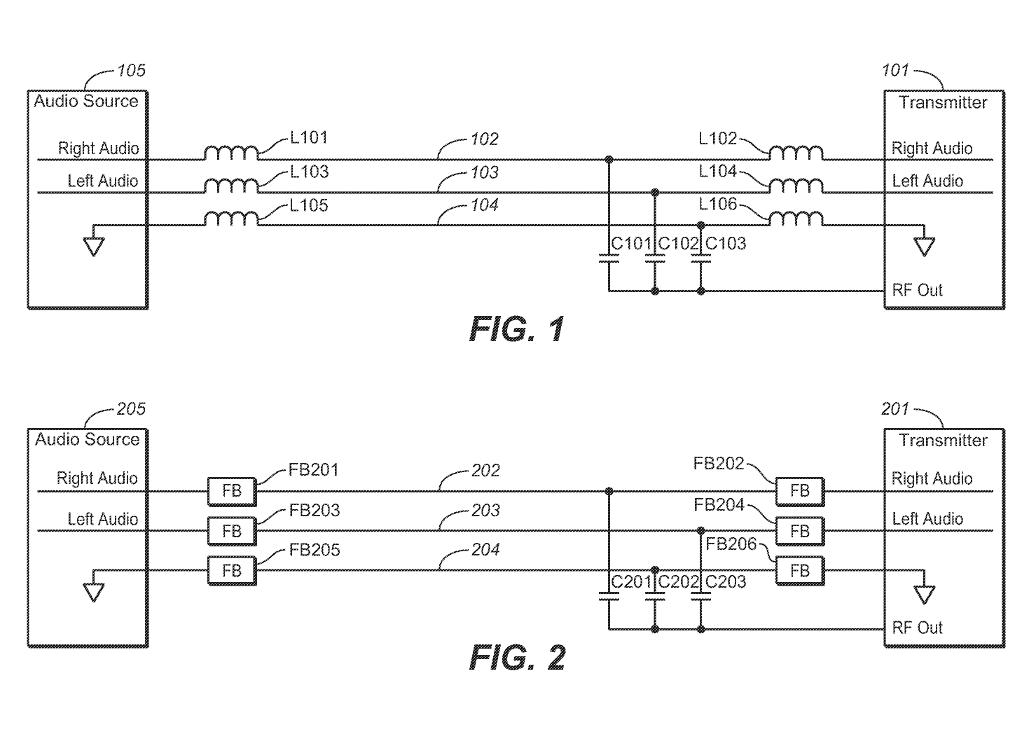

Referring first to FIG. 1, there is shown a circuit diagram of an embodiment of the present invention wherein the output of a radio frequency transmitter is capacitively coupled to audio signal wires for use as antenna elements, and inductors are used to isolate the audio and radio frequency signals.

It can be seen in FIG. 1 that transmitter 101 is connected to an audio source 105 by audio signal wires configured to provide a conduit for stereo audio signals. Audio source 105 transmits the stereo signal's right-side audio signals via inductor L101, audio wire 102 and inductor L102 to the right audio input of transmitter 101. Audio source 105 transmits the stereo signal's left-side audio signals via inductor L103, audio wire 103 and inductor L104 to the left audio input of transmitter 101. Audio source 105 and transmitter 101 share a common ground through inductor L105, audio wire 104 and inductor L106.

It can also be seen in FIG. 1 that transmitter 101 has its radio frequency output coupled to audio wires 102, 103 and 104 via capacitors C101, C102 and C103. In this configuration, audio wires 102, 103 and 104 are acting as antenna elements for the radio frequency signals transmitted by transmitter 101.

Inductor L101 acts as a band-pass filter for audio, allowing right-side audio from audio source 105 to pass onto wire 102 and through inductor L102 (which also acts as a band-pass filter to the audio) into the right audio input of transmitter 101. Inductor L103 acts as a band-pass filter for audio, allowing left-side audio from audio source 105 to pass onto wire 103 and through inductor L104 (which also acts as a band-pass filter to the audio) into the left audio input of transmitter 101. Inductor L101 also acts as band-stop filter to any radio frequency signals present on wire 102, preventing those radio frequency signals from reaching the right-side audio output of audio source 105. Inductor L102 also acts as band-stop filter to any radio frequency signals present on wire 102, preventing those radio frequency signals from reaching the right audio input of transmitter 101. Inductor L103 also acts as band-stop filter to any radio frequency signals present on wire 103, preventing those radio frequency signals from reaching the left-side audio output of audio source 105. Inductor L104 also acts as band-stop filter to any radio frequency signals present on wire 103, preventing those radio frequency signals from reaching the left audio input of transmitter 101. Inductor L105 also acts as band-stop filter to any radio frequency signals present on wire 104, preventing those radio frequency signals from reaching the common ground connection of audio source 105. Inductor L106 also acts as band-stop filter to any radio frequency signals present on wire 104, preventing those radio frequency signals from reaching the common ground connection of transmitter 101.

Referring now to FIG. 2, there is shown a circuit diagram of an embodiment of the present invention wherein the output of a radio frequency transmitter is capacitively coupled to audio signal wires for use as antenna elements, and ferrite beads are used to isolate the audio and radio frequency signals.

It can be seen in FIG. 2 that transmitter 201 is connected to audio source 205 by audio signal wires configured to provide a conduit for stereo audio signals. Audio source 205 transmits the stereo signal's right-side audio signals via ferrite bead FB201, audio wire 202 and ferrite bead FB202 to the right audio input of transmitter 201. Audio source 205 transmits the stereo signal's left-side audio signals via ferrite bead FB203, audio wire 203 and ferrite bead FB204 to the left audio input of transmitter 201. Audio source 205 and transmitter 201 share a common ground through ferrite bead FB205, audio wire 204 and ferrite bead FB206.

It can also be seen in FIG. 2 that transmitter 201 has its radio frequency output coupled to audio wires 202, 203 and 204 via capacitors C201, C202 and C203. In this configuration, audio wires 202, 203 and 204 are acting as antenna elements for the radio frequency signals transmitted by transmitter 201.

Ferrite bead FB201 acts as a band-pass filter for audio, allowing right-side audio from audio source 205 to pass onto wire 202 and through ferrite bead FB202 (which also acts as a band-pass filter to the audio) into the right audio input of transmitter 201. Ferrite bead FB203 acts as a band-pass filter for audio, allowing left-side audio from audio source 105 to pass onto wire 203 and through ferrite bead FB204 (which also acts as a band-pass filter to the audio) into the left audio input of transmitter 201. Ferrite bead FB201 also acts as band-stop filter to any radio frequency signals present on wire 202, preventing those radio frequency signals from reaching the right-side audio output of audio source 205. Ferrite bead FB202 also acts as band-stop filter to any radio frequency signals present on wire 202, preventing those radio frequency signals from reaching the right audio input of transmitter 201. Ferrite bead FB203 also acts as band-stop filter to any radio frequency signals present on wire 203, preventing those radio frequency signals from reaching the left-side audio output of audio source 205. Ferrite bead FB204 also acts as band-stop filter to any radio frequency signals present on wire 203, preventing those radio frequency signals from reaching the left audio input of transmitter 201. Ferrite bead FB205 also acts as band-stop filter to any radio frequency signals present on wire 204, preventing those radio frequency signals from reaching the common ground connection of audio source 205. Ferrite bead FB206 also acts as band-stop filter to any radio frequency signals present on wire 204, preventing those radio frequency signals from reaching the common ground connection of transmitter 201.

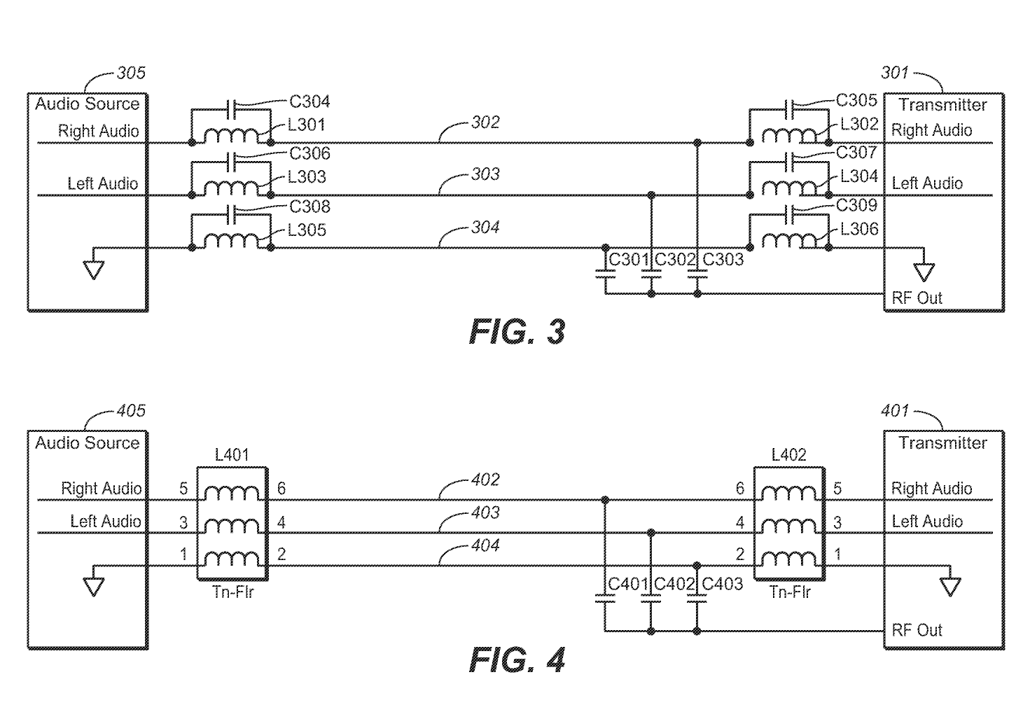

Referring next to FIG. 3, there is shown a circuit diagram of an embodiment of the present invention wherein the output of a radio frequency transmitter is capacitively coupled to audio signal wires for use as antenna elements, and inductors and capacitors are used to isolate the audio and radio frequency signals.

It can be seen in FIG. 3 that transmitter 301 is connected to audio source 305 by audio signal wires configured to provide a conduit for stereo audio signals. Audio source 305 transmits the stereo signal's right-side audio signals via the tank circuit comprising capacitor C304 and inductor L301, audio wire 302 and the tank circuit comprising capacitor C305 and inductor L302 to the right audio input of transmitter 301. Audio source 305 transmits the stereo signal's left-side audio signals via the tank circuit comprising capacitor C306 and inductor L303, audio wire 303 and the tank circuit comprising capacitor C307 and inductor L304 to the left audio input of transmitter 301. Audio source 305 and transmitter 301 share a common ground through via the tank circuit comprising capacitor C308 and inductor L305, audio wire 304 and the tank circuit comprising capacitor C309 and inductor L306.

It can also be seen in FIG. 3 that transmitter 301 has its radio frequency output coupled to audio wires 302, 303 and 304 via capacitors C301, C302 and C303. In this configuration, audio wires 302, 303 and 304 are acting as antenna elements for the radio frequency signals transmitted by transmitter 301.

The tank circuit comprising capacitor C304 and inductor L301 acts as a band-pass filter for audio, allowing right-side audio from audio source 305 to pass onto wire 302 and through the tank circuit comprising capacitor C305 and inductor L302 (which also acts as a band-pass filter to the audio) into the right audio input of transmitter 301. The tank circuit comprising C305 and inductor L302 acts as a band-pass filter for audio, allowing left-side audio from audio source 105 to pass onto wire 203 and through ferrite bead FB204 (which also acts as a band-pass filter to the audio) into the left audio input of transmitter 201. The tank circuit comprising capacitor C304 and inductor L301 also acts as band-stop filter to any radio frequency signals present on wire 302, preventing those radio frequency signals from reaching the right-side audio output of audio source 305. The tank circuit comprising capacitor C305 and inductor L302 also acts as band-stop filter to any radio frequency signals present on wire 302, preventing those radio frequency signals from reaching the right audio input of transmitter 301. The tank circuit comprising capacitor C306 and inductor L303 also acts as band-stop filter to any radio frequency signals present on wire 303, preventing those radio frequency signals from reaching the left-side audio output of audio source 305. The tank circuit comprising capacitor C307 and inductor L304 also acts as band-stop filter to any radio frequency signals present on wire 303, preventing those radio frequency signals from reaching the left audio input of transmitter 301. The tank circuit comprising capacitor C308 and inductor L305 also acts as band-stop filter to any radio frequency signals present on wire 304, preventing those radio frequency signals from reaching the common ground connection of audio source 305. The tank circuit comprising capacitor C309 and inductor L306 also acts as band-stop filter to any radio frequency signals present on wire 304, preventing those radio frequency signals from reaching the common ground connection of transmitter 301.

Turning next to FIG. 4, there is shown a circuit diagram of an embodiment of the present invention wherein the output of a radio frequency transmitter is capacitively coupled to audio signal wires for use as antenna elements, and the windings of a filar-wire, common-mode radio frequency choke are used to isolate the audio and radio frequency signals.

It can be seen in FIG. 4 that transmitter 401 is connected to audio source 405 by audio signal wires configured to provide a conduit for stereo audio signals. Audio source 405 transmits the stereo signal's right-side audio signals via radio frequency choke L401 (connecting through radio frequency choke L401 terminals 5 and 6), audio wire 402 and radio frequency choke L402 (connecting through radio frequency choke L402 terminals 5 and 6) to the right audio input of transmitter 401. Audio source 405 transmits the stereo signal's left-side audio signals via radio frequency choke L401 (connecting through radio frequency choke L401 terminals 3 and 4), audio wire 403 and radio frequency choke L402 (connecting through radio frequency choke L402 terminals 3 and 4) to the left audio input of transmitter 401. Audio source 405 and transmitter 401 share a common ground through radio frequency choke L401 (connecting through radio frequency choke L401 terminals 1 and 2), audio wire 404 and radio frequency choke L402 (connecting through radio frequency choke L402 terminals 1 and 2).

It can also be seen in FIG. 4 that transmitter 401 has its radio frequency output coupled to audio wires 402, 403 and 404 via capacitors C401, C402 and C403. In this configuration, audio wires 402, 403 and 404 are acting as antenna elements for the radio frequency signals transmitted by transmitter 401.

Radio frequency choke L401 (between radio frequency choke L401 terminals 5 and 6) acts as a band-pass filter for audio, allowing right-side audio from audio source 405 to pass onto wire 402 and through radio frequency choke L402 (through radio frequency choke L402 terminals 5 and 6), which also acts as a band-pass filter to the audio, into the right audio input of transmitter 401. Radio frequency choke L401 (between radio frequency choke L401 terminals 3 and 4) acts as a band-pass filter for audio, allowing left-side audio from audio source 405 to pass onto wire 402 and through radio frequency choke L402 (through radio frequency choke L402 terminals 3 and 4), which also acts as a band-pass filter to the audio, into the left audio input of transmitter 401. Radio frequency choke L401 (between radio frequency choke L401 terminals 5 and 6) also acts as band-stop filter to any radio frequency signals present on wire 402, preventing those radio frequency signals from reaching the right-side audio output of audio source 405. Radio frequency choke L402 (between radio frequency choke L402 terminals 5 and 6) also acts as band-stop filter to any radio frequency signals present on wire 402, preventing those radio frequency signals from reaching the right audio input of transmitter 401. Radio frequency choke L401 (between radio frequency choke L401 terminals 3 and 4) also acts as band-stop filter to any radio frequency signals present on wire 403, preventing those radio frequency signals from reaching the left-side audio output of audio source 405. Radio frequency choke L402 (between radio frequency choke L402 terminals 3 and 4) also acts as band-stop filter to any radio frequency signals present on wire 403, preventing those radio frequency signals from reaching the left audio input of transmitter 401. Radio frequency choke L401 (between radio frequency choke L401 terminals 1 and 2) also acts as band-stop filter to any radio frequency signals present on wire 404, preventing those radio frequency signals from reaching the common ground connection of audio source 405. Radio frequency choke L402 (between radio frequency choke L402 terminals 1 and 2) also acts as band-stop filter to any radio frequency signals present on wire 404, preventing those radio frequency signals from reaching the common ground connection of transmitter 401.

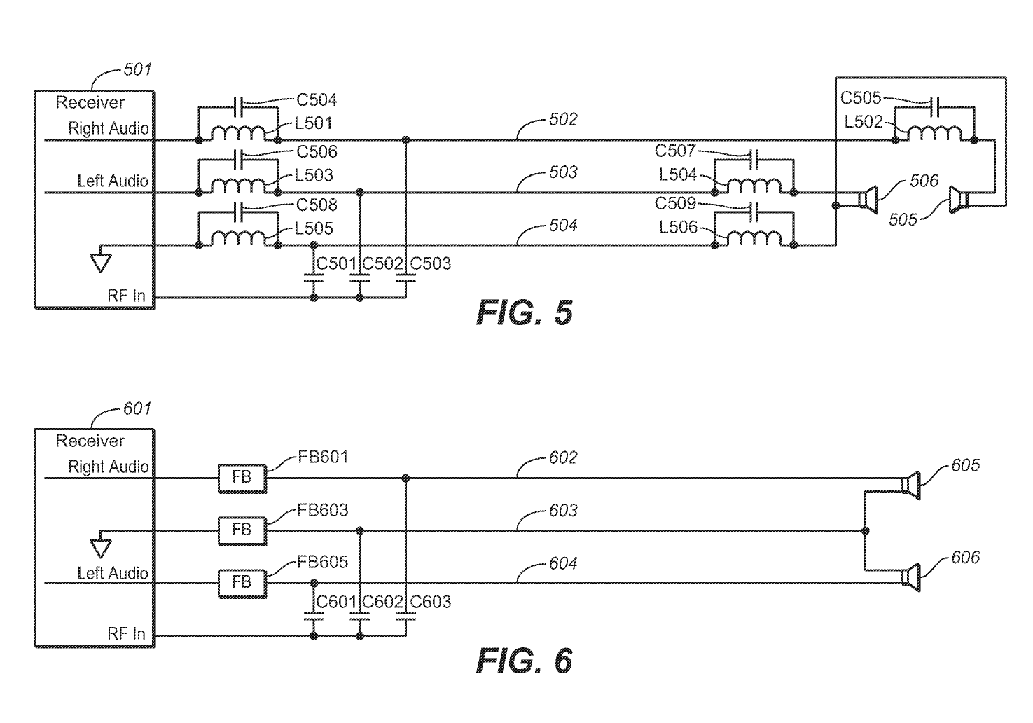

Referring now to FIG. 5, there is shown a circuit diagram of an embodiment of the present invention wherein the input of a radio frequency receiver is capacitively coupled to audio signal wires for use as antenna elements, and inductors and capacitors are used to isolate the audio and radio frequency signals.

It can be seen in FIG. 5 that receiver 501 is connected to speakers 505 and 506 by audio signal wires configured to provide a conduit for stereo audio signals. Speaker 505 receives the stereo signal's right-side audio signals from receiver 501 via the tank circuit comprising capacitor C504 and inductor L501, audio wire 502 and the tank circuit comprising capacitor C505 and inductor L502. Speaker 506 receives the stereo left-side audio signals from receiver 501 via the tank circuit comprising capacitor C506 and inductor L503, audio wire 503 and the tank circuit comprising capacitor C507 and inductor L504. Speakers 505, 506 and receiver 501 share a common ground through the tank circuit comprising capacitor C508 and inductor L505, audio wire 504 and the tank circuit comprising capacitor C509 and inductor L506.

It can also be seen in FIG. 5 that receiver 501 has its radio frequency input coupled to audio wires 502, 503 and 504 via capacitors C501, C502 and C503. In this configuration, audio wires 502, 503 and 504 are acting as antenna elements for the radio frequency signals received by receiver 501.

The tank circuit comprising capacitor C504 and inductor L501 acts as a band-pass filter for audio, allowing right-side audio from receiver 501 to pass onto wire 502 and through the tank circuit comprising capacitor C505 and inductor L502 (which also acts as a band-pass filter to the audio) into speaker 505. The tank circuit comprising capacitor C506 and inductor L503 acts as a band-pass filter for audio, allowing left-side audio from receiver 501 to pass onto wire 502 and through the tank circuit comprising capacitor C507 and inductor L504 (which also acts as a band-pass filter to the audio) into speaker 506. The tank circuit comprising capacitor C504 and inductor L501 also acts as band-stop filter to any radio frequency signals present on wire 502, preventing those radio frequency signals from reaching the right-side audio output of receiver 501. The tank circuit comprising capacitor C505 and inductor L502 also acts as band-stop filter to any radio frequency signals present on wire 502, preventing those radio frequency signals from reaching speaker 505. The tank circuit comprising capacitor C506 and inductor L503 also acts as band-stop filter to any radio frequency signals present on wire 503, preventing those radio frequency signals from reaching the left-side audio output of receiver 501. The tank circuit comprising capacitor C507 and inductor L504 also acts as band-stop filter to any radio frequency signals present on wire 503, preventing those radio frequency signals from reaching the left audio output of receiver 501. The tank circuit comprising capacitor C508 and inductor L505 also acts as band-stop filter to any radio frequency signals present on wire 504, preventing those radio frequency signals from reaching the common ground connection of receiver 501. The tank circuit comprising capacitor C509 and inductor L506 also acts as band-stop filter to any radio frequency signals present on wire 504, preventing those radio frequency signals from reaching the common ground of speakers 505 and 506.

Referring now to FIG. 6, there is shown a circuit diagram of an embodiment of the present invention wherein the input of a radio frequency receiver is capacitively coupled to audio signal wires for use as antenna elements, and ferrite beads are used to isolate the audio and radio frequency signals.

It can be seen in FIG. 6 that receiver 601 is connected to speakers 605 and 606 by audio signal wires configured to provide a conduit for stereo audio signals. Speaker 605 receives the stereo signal's right-side audio signals from receiver 601 via ferrite bead FB601, audio wire 602 and ferrite bead FB602. Speaker 606 receives the stereo signal's left-side audio signals from receiver 601 via ferrite bead FB603, audio wire 603 and ferrite bead FB604. Speakers 605, 606 and receiver 601 share a common ground through ferrite bead FB605, audio wire 604 and ferrite bead FB606.

It can also be seen in FIG. 6 that receiver 601 has its radio frequency input coupled to audio wires 602, 603 and 604 via capacitors C601, C602 and C603. In this configuration, audio wires 602, 603 and 604 are acting as antenna elements for the radio frequency signals received by receiver 601.

Ferrite bead FB601 acts as a band-pass filter for audio, allowing right-side audio from receiver 601 to pass onto wire 602. Ferrite bead FB603 acts as a band-pass filter for audio, allowing left-side audio from receiver 601 to pass onto wire 603 into speaker 605. Ferrite bead FB601 acts as band-stop filter to any radio frequency signals present on wire 602, preventing those radio frequency signals from reaching the right-side audio output of receiver 601. Ferrite bead FB603 also acts as band-stop filter to any radio frequency signals present on wire 603, preventing those radio frequency signals from reaching the left-side audio output of receiver 601. Ferrite bead FB605 acts as band-stop filter to any radio frequency signals present on wire 604, preventing those radio frequency signals from reaching the common ground connection of receiver 601.

The foregoing disclosure is sufficient to enable those with skill in the relevant art to practice the invention without undue experimentation. The disclosure further provides the best mode of practicing the invention now contemplated by the inventor.

While the particular circuits shown and disclosed in detail are fully capable of attaining the objects and providing the advantages stated herein, it is to be understood that these embodiments are merely illustrative of the preferred embodiments of the invention and that no limitations are intended concerning the detail of construction or design shown other than as defined in the appended claims. Accordingly, the proper scope of the present invention should be determined only by the broadest interpretation of the appended claims so as to encompass obvious modifications as well as all relationships equivalent to those illustrated in the drawings and described in the specification.

What is claimed as invention is:

1. An antenna system for a radio frequency transmitter and/or receiver in an audio playback device, said antenna system including a conductor in an interconnecting cable, wherein said conductor is isolated at RF from said audio playback device at the opposite end of said conductor, while also being tightly coupled to said audio playback device at audio frequencies and/or DC.

2. The antenna system of claim 1, wherein an output signal of the radio frequency transmitter is capacitively coupled to audio signal wires for use as antenna elements, and further including inductors for isolating the audio and radio frequency signals.

3. The antenna system of claim 1, wherein an output signal of the radio frequency transmitter is capacitively coupled to audio signal wires for use as antenna elements, and including ferrite beads for isolating audio and radio frequency signals.

4. The antenna system of claim 1, wherein an output signal of the radio frequency transmitter is capacitively coupled to audio signal wires for use as antenna elements, and including inductors and capacitors for isolating audio and radio frequency signals.

5. The antenna system of claim 1, wherein an output signal of the radio frequency transmitter is capacitively coupled to audio signal wires for use as antenna elements, and including windings of a filar-wire, common-mode radio frequency choke for isolating audio and radio frequency signals.

6. The antenna system of claim 1, wherein an input signal to the radio frequency receiver is capacitively coupled to audio signal wires for use as antenna elements, and including inductors and capacitors for isolating audio and radio frequency signals.

7. The antenna system of claim 1, wherein an input signal to the radio frequency receiver is capacitively coupled to audio signal wires for use as antenna elements, and including ferrite beads for isolating audio and radio frequency signals.

8. An antenna system for a radio frequency transmitter and/or receiver, comprising:
a transmitter having a left-side audio input and a right-side audio input;
an audio source having a left-side audio output and a right-side audio output;
a first audio signal wire connecting said transmitter to said audio source for transmitting a stereo signal right-side audio signal through said first audio signal wire to said right-side audio output of said audio source;
a first band pass filter and a first band stop filter disposed on said first audio signal wire between said transmitter and said audio source;
a second audio signal wire connecting said transmitter to said audio source for transmitting a stereo signal left-side audio signal through said second audio signal wire to said left-side audio output of said audio source;
a second band pass filter and second band stop filter disposed on said second audio signal wire between said transmitter and said audio source;
a third audio signal wire for use as a common ground shared by said audio source and said transmitter;
a third band pass filter and third band stop filter disposed on said third audio signal wire between said transmitter and said audio source; and
first through third capacitors disposed on said first through third audio signal wires, respectively, between each of said first band pass and first band stop filters, said second band pass and second band stop filters, and said third band pass and band stop filters, respectively;
wherein said first through third audio signal wires act as antenna elements for radio frequency signals transmitted by said transmitter.

9. The antenna system of claim 8, wherein said first band pass filter is a first inductor, said first band stop filter is a second inductor, said second band pass filter is a third inductor, said second band stop filter is a fourth inductor, said third band pass filter is a fifth inductor, and said third band stop filter is a sixth inductor; and
wherein said first inductor acts as a band-pass filter for audio signals, allowing right-side audio signals from said audio source to pass onto said first audio signal wire and through said second inductor, which also acts as a band-pass filter to audio signals, and into said right audio input of said transmitter, and wherein said first inductor also acts as band-stop filter to radio frequency signals present on said first audio signal wire, thus preventing radio frequency signals from reaching said right-side audio output of said audio source, and wherein said second inductor acts as band-stop filter to radio frequency signals present on said first audio signal wire, thereby preventing radio frequency signals from reaching said right audio input of said transmitter;
and further wherein said third inductor acts as a band-pass filter for audio signals, allowing left-side audio signals from said audio source to pass onto said second audio signal wire and through said fourth inductor, which also acts as a band-pass filter to audio signals, into said left audio input of said transmitter, and said third inductor also acts as band-stop filter to radio frequency signals present on said second audio signal wire, thus preventing radio frequency signals from reaching said left-side audio output of said audio source, and said fourth inductor acts as band-stop filter to radio frequency signals present on said second audio signal wire, thus preventing radio frequency signals from reaching said left audio input of said transmitter;
and wherein said fifth inductor acts as band-stop filter to radio frequency signals present on said third audio signal wire, preventing radio frequency signals from reaching said common ground connection of said audio source, and said sixth inductor acts as band-stop filter to radio frequency signals present on said third audio signal wire, thus preventing radio frequency signals from reaching said common ground connection of said transmitter.

10. The antenna system of claim 8, wherein said first band pass filter is a first ferrite bead, said first band stop filter is a second ferrite bead, said second band pass filter is a third ferrite bead, said second band stop filter is a fourth ferrite bead, said third band pass filter is a fifth ferrite bead, and said third band stop filter is a sixth ferrite bead; and
wherein said first ferrite bead acts as a band-pass filter for audio signals, allowing right-side audio signals from said audio source to pass onto said first audio signal wire and through said second ferrite bead, which also acts as a band-pass filter to audio signals, and into said right audio input of said transmitter, and wherein said first ferrite bead also acts as band-stop filter to radio frequency signals present on said first audio signal wire, thus preventing radio frequency signals from reaching said right-side audio output of said audio source, and wherein said second ferrite bead acts as band-stop filter to radio frequency signals present on said first audio signal wire, thereby preventing radio frequency signals from reaching said right audio input of said transmitter;
and further wherein said third ferrite bead acts as a band-pass filter for audio signals, allowing left-side audio signals from said audio source to pass onto said second audio signal wire and through said fourth ferrite bead, which also acts as a band-pass filter to audio signals, into said left audio input of said transmitter, and said third ferrite bead also acts as band-stop filter to radio frequency signals present on said second audio signal wire, thus preventing radio frequency signals from reaching said left-side audio output of said audio source, and said fourth ferrite bead acts as band-stop filter to radio frequency signals present on said second audio signal wire, thus preventing radio frequency signals from reaching said left audio input of said transmitter;
and wherein said fifth ferrite bead acts as band-stop filter to radio frequency signals present on said third audio signal wire, preventing radio frequency signals from reaching said common ground connection of said audio source, and said sixth ferrite bead acts as band-stop filter to radio frequency signals present on said third audio signal wire, thus preventing radio frequency signals from reaching said common ground connection of said transmitter.

11. The antenna system of claim 8, wherein said first band pass filter is a first tank circuit, said first band stop filter is a second tank circuit, said second band pass filter is a third tank circuit, said second band stop filter is a fourth tank circuit, said third band pass filter is a fifth tank circuit, and said third band stop filter is a sixth tank circuit; and
wherein said first tank circuit acts as a band-pass filter for audio signals, allowing right-side audio signals from said audio source to pass onto said first audio signal wire and through said second tank circuit, which also acts as a band-pass filter to audio signals, and into said right audio input of said transmitter, and wherein said first tank circuit also acts as band-stop filter to radio frequency signals present on said first audio signal wire, thus preventing radio frequency signals from reaching said right-side audio output of said audio source, and wherein said second tank circuit acts as band-stop filter to radio frequency signals present on said first audio signal wire, thereby preventing radio frequency signals from reaching said right audio input of said transmitter;
and further wherein said third tank circuit acts as a band-pass filter for audio signals, allowing left-side audio signals from said audio source to pass onto said second audio signal wire and through said fourth tank circuit, which also acts as a band-pass filter to audio signals, into said left audio input of said transmitter, and said third tank circuit also acts as band-stop filter to radio frequency signals present on said second audio signal wire, thus preventing radio frequency signals from reaching said left-side audio output of said audio source, and said fourth tank circuit acts as band-stop filter to radio frequency signals present on said second audio signal wire, thus preventing radio frequency signals from reaching said left audio input of said transmitter;
and wherein said fifth tank circuit acts as band-stop filter to radio frequency signals present on said third audio signal wire, preventing radio frequency signals from reaching said common ground connection of said audio source, and said sixth tank circuit acts as band-stop filter to radio frequency signals present on said third audio signal wire, thus preventing radio frequency signals from reaching said common ground connection of said transmitter.

12. An antenna system for a radio frequency transmitter and/or receiver, comprising:
a transmitter having a left-side audio input and a right-side audio input;
an audio source having a left-side audio output and a right-side audio output;
a first audio signal wire connecting said transmitter to said audio source for transmitting a stereo signal right-side audio signal through said first audio signal wire to said right-side audio output of said audio source;
a second audio signal wire connecting said transmitter to said audio source for transmitting a stereo signal left-side audio signal through said second audio signal wire to said left-side audio output of said audio source;
a third audio signal wire for use as a common ground shared by said audio source and said transmitter;
first and second radio frequency chokes disposed on each of said first through third audio signal wires between said audio source and said transmitter;
first through third capacitors disposed on said first through third audio signal wires, respectively, between each of said first and second radio frequency chokes;
wherein said first through third audio signal wires act as antenna elements for radio frequency signals transmitted by said transmitter.

13. The antenna system of claim 12, wherein said first and second radio frequency chokes act as a band-pass filter for audio signals, allowing right-side audio signals from said audio source to pass onto said first audio signal wire and through said second radio frequency choke, which also acts as a band-pass filter to audio signals, and into said right audio input of said transmitter, and wherein said first radio frequency choke also acts as band-stop filter to radio frequency signals present on said first audio signal wire, thus preventing radio frequency signals from reaching said right-side audio output of said audio source, and wherein said second radio frequency choke acts as band-stop filter to radio frequency signals present on said first audio signal wire, thereby preventing radio frequency signals from reaching said right audio input of said transmitter;
and further wherein said first radio frequency choke acts as a band-pass filter for audio signals, allowing left-side audio signals from said audio source to pass onto said second audio signal wire and through said fourth radio frequency choke, which also acts as a band-pass filter to audio signals, into said left audio input of said transmitter, and said second radio frequency choke also acts as band-stop filter to radio frequency signals present on said second audio signal wire, thus preventing radio frequency signals from reaching said left-side audio output of said audio source, and said second radio frequency choke acts as band-stop filter to radio frequency signals present on said second audio signal wire, thus preventing radio frequency signals from reaching said left audio input of said transmitter;
and wherein said first radio frequency choke acts as band-stop filter to radio frequency signals present on said third audio signal wire, preventing radio frequency signals from reaching said common ground connection of said audio source, and said second radio frequency choke acts as band-stop filter to radio frequency signals present on said third audio signal wire, thus preventing radio frequency signals from reaching said common ground connection of said transmitter.

14. An antenna system, comprising
a radio frequency receiver having a right-side audio output signal and a left-side audio output signal;
at least two speakers;
a first audio signal wire connecting said right-side audio signal output to a first speaker; a second audio signal wire connecting said left-side audio signal output to a second speaker;
first and second tank circuit disposed on said first audio signal wire between said receiver and said first speaker;
third and fourth tank circuits disposed on said second audio signal wire between said receiver and said second speaker;
a third audio signal wire for use as a common ground by said receiver and said speakers; and
fifth and sixth tank circuits disposed on said third audio signal wire between said receiver and said speakers;
wherein said audio signal wires act as antenna elements for radio frequency signals received by said receiver.

15. The antenna system of claim 14, wherein said first tank circuit acts as a band-pass filter for audio signals, allowing right-side audio signals from said receiver to pass onto said first audio signal wire and through said second tank circuit, which also acts as a band-pass filter to audio signals, and into said first speaker;
wherein said third tank circuit acts as a band-pass filter for audio signals, allowing left-side audio signals from said receiver to pass onto said second audio signal wire and through said fourth tank circuit, which also acts as a band-pass filter to audio signals, and into said second speaker;
wherein said first tank circuit acts as band-stop filter to radio frequency signals present on said first audio signal wire, thereby preventing radio frequency signals from reaching said right-side audio signal output of said receiver;
wherein said second tank circuit acts as band-stop filter to radio frequency signals present on said first audio signal wire, preventing radio frequency signals from reaching said first speaker;
wherein said third tank circuit acts as band-stop filter to radio frequency signals present on said second audio signal wire, preventing radio frequency signals from reaching said left-side audio signal output of said receiver;
wherein said fourth tank circuit acts as band-stop filter to radio frequency signals present on said second audio signal wire, preventing radio frequency signals from reaching said left audio signal output of said receiver;
wherein said fifth tank circuit acts as band-stop filter to radio frequency signals present on said third audio signal wire, preventing radio frequency signals from reaching said common ground connection of said receiver; and
wherein said sixth tank circuit acts as band-stop filter to radio frequency signals present on said third audio signal wire, preventing radio frequency signals from reaching said common ground of said first and second speakers.
